(19) United States
(12) Patent Application Publication
(10) Pub. No.: US 2020/0053920 A1
(43) Pub. Date: Feb. 13, 2020

(54) HIGH-DIELECTRIC-LOSS COMPOSITES FOR ELECTROMAGNETIC INTERFERENCE (EMI) APPLICATIONS

(71) Applicant: 3M INNOVATIVE PROPERTIES COMPANY, St. Paul, MN (US)

(72) Inventor: Dipankar Ghosh, Oakdale, MN (US)

(21) Appl. No.: 16/344,412

(22) PCT Filed: Oct. 26, 2017
(86) PCT No.: PCT/US2017/058488

§ 371 Date: Apr. 24, 2019

Related U.S. Application Data
(60) Provisional application No. 62/414,971, filed on Oct. 31, 2016.
(60) Provisional application No. 62/491,316, filed on Apr. 28, 2017.

(51) Int. Cl. H05K 9/00; C08J 9/00; C08K 3/22; C08K 3/04; C08K 3/36; C08K 9/06; C08K 13/06

(52) U.S. Cl. CPC H05K 9/0083; C08J 9/008; C08K 3/22; C08K 3/04; C08K 3/36; C08K 9/06; C08K 2003/2248; C08J 2205/052; C08J 2205/05; C08J 2383/04; C08K 2201/011; C08K 2201/001; C08K 2201/01; C08K 13/06

(57) ABSTRACT

Electromagnetic interference (EMI) shielding composites and methods of making and using the same are described. The composites include high-loading-level ceramic particles distributed in a low-dielectric-loss matrix material having a dielectric loss tangent in the range of about 0.0001 to about 0.005. In one case, the composite includes CuO particles distributed in silicone. The composites exhibit dielectric absorber properties in the high frequency range.

### TECHNICAL FIELD

The present disclosure relates to high-dielectric-loss composites or articles for electromagnetic interference (EMI) applications, and methods of making and using the same.

### BACKGROUND

Electromagnetic interference (EMI) is becoming a more significant factor in electronic industry because of the growing need for more powerful and compact electronic products. The EMI shielding of electronic devices and radiation sources is an important consideration in the reliable operation of devices in electronic devices. Electromagnetic (EM) noise needs to be reduced to enhance the signal integrity of these communication devices. EMI shielding may be achieved by reflection of the electromagnetic (EM) wave, absorption of the wave, or both. It is most common for a highly conductive metal sheet (known as an EM shield) to be used to reflect undesired EM waves. However, in some cases, reflecting the EM waves is not sufficient or may cause further problems. This leads to the requirement for providing EMI absorber and shielding materials and methods for absorbing EM waves, especially in a high frequency regime, for example, 1 to 40 GHz, or 1 to 80 GHz, and harmonics associated with such base frequencies. Polymer composites with EMI mitigation properties were described in, for example, WO2014/130431 (Dipankar et al.).

### SUMMARY

There is a desire to use more effective shielding or absorbing materials with improved electromagnetic properties in electronic devices for electromagnetic interference (EMI) applications, especially in a high frequency regime. Briefly, in one aspect, the present disclosure describes an electromagnetic interference (EMI) shielding composite including about 5 to about 50 wt. % of a low-dielectric-loss matrix material, and about 50 to about 95 wt. % copper(II) oxide (CuO) particles distributed inside the low-dielectric-loss matrix material. The low-dielectric-loss matrix material has a dielectric loss tangent in the range of about 0.0001 to about 0.005.

In another aspect, the present disclosure describes a method of making an electromagnetic interference (EMI) shielding composite. The method includes compounding ceramic particles with a low-dielectric-loss polymer matrix to form the composite. The composite includes about 5 to about 50 wt. % of a low-dielectric-loss matrix material, and about 50 to about 95 wt. % copper(II) oxide (CuO) particles distributed inside the low-dielectric-loss matrix material. The low-dielectric-loss matrix material has a dielectric loss tangent in the range of about 0.0001 to about 0.005. In some embodiments, the copper(II) oxide (CuO) particles are compounded with silicone to form the composite.

In another aspect, the present disclosure describes an electromagnetic interference (EMI) shielding article comprising the composite including about 5 to about 50 wt. % of a low-dielectric-loss matrix material, and about 50 to about 95 wt. % copper(II) oxide (CuO) particles distributed inside the low-dielectric-loss matrix material. The article is capable of shielding, primarily by absorbing, electromagnetic radiation in the range of about 0.01 GHz to about 100 GHz, about 1 GHz to about 80 GHz, or about 20 GHz to about 40 GHz.

Various unexpected results and advantages are obtained in exemplary embodiments of the disclosure. One such advantage of exemplary embodiments of the present disclosure is that the EMI shielding composites include a high-loading-level of ceramic particles (e.g., CuO particles) distributed in a low-dielectric-loss matrix material (e.g., silicone). The composites can act as lossy dielectric absorbers in a high frequency regime of, for example, about 0.01 GHz to about 100 GHz, about 1 GHz to about 80 GHz, or about 20 GHz to about 40 GHz.

Various aspects and advantages of exemplary embodiments of the disclosure have been summarized. The above Summary is not intended to describe each illustrated embodiment or every implementation of the present certain exemplary embodiments of the present disclosure. The Drawings and the Detailed Description that follow more particularly exemplify certain preferred embodiments using the principles disclosed herein.

### BRIEF DESCRIPTION OF THE DRAWINGS

The disclosure may be more completely understood in consideration of the following detailed description of various embodiments of the disclosure in connection with the accompanying figures, in which:

FIG. 1 illustrates test results for Examples 1 and 2 showing plots for real and imaginary parts of dielectric permittivity of polymer composite versus frequency.

FIG. 2 illustrates test results for Examples 3 and 4 showing plots for dielectric loss tangent (tan δ=ε″/ε′) of polymer composite versus frequency.

FIG. 3 illustrates test results for Examples 1 and 3 showing plots for dielectric loss tangent (tan δ=ε″/ε′) of polymer composite versus frequency.

FIG. 4 illustrates test results for Examples 5-7 showing plots for real and imaginary parts of dielectric permittivity of polymer composite versus frequency.

FIG. 5 illustrates test results for Examples 5-7 showing plots for dielectric loss tangent (tan δ=ε″/ε′) of polymer composite versus frequency.

In the drawings, like reference numerals indicate like elements. While the above-identified drawing, which may not be drawn to scale, sets forth various embodiments of the present disclosure, other embodiments are also contemplated, as noted in the Detailed Description. In all cases, this disclosure describes the presently disclosed disclosure by way of representation of exemplary embodiments and not by express limitations. It should be understood that numerous other modifications and embodiments can be devised by those skilled in the art, which fall within the scope and spirit of this disclosure.

### DETAILED DESCRIPTION

For the following Glossary of defined terms, these definitions shall be applied for the entire application, unless a different definition is provided in the claims or elsewhere in the specification.

### Glossary

Certain terms are used throughout the description and the claims that, while for the most part are well known, may require some explanation. It should be understood that:

The terms “polymer” and “polymeric material” refer to both materials prepared from one monomer such as a homopolymer or to materials prepared from two or more monomers such as a copolymer, terpolymer, or the like. Likewise, the term “polymerize” refers to the process of making a polymeric material that can be a homopolymer, copolymer, terpolymer, or the like. The terms “copolymer” and “copolymeric material” refer to a polymeric material prepared from at least two monomers.

The terms “low-dielectric-loss matrix material” as used herein refers to a matrix material that has a dielectric loss tangent in the range of, for example, from about 0.0001 to about 0.005, from about 0.0001 to about 0.0045, from about 0.0001 to about 0.004, from about 0.0001 to about 0.0035, from about 0.0001 to about 0.003, from about 0.0001 to about 0.0025, or from about 0.0001 to about 0.002 over the frequency range of interest. In some embodiments, silicone (e.g., silicone made of two-part silicone elastomer kit commercially available from Dow Corning (Midland, Mich., USA) under the trade designation Silicone Sylgard 184) can be used as the low-dielectric-loss matrix, which has a dielectric loss tangent of about 0.0013 at 100 kHz. The dielectric loss tangent, typically referred to as tan δ, is a frequency dependent parameter of a dielectric material that quantifies its inherent dissipation of electromagnetic energy. The term refers to the tangent of the angle in a complex plane between the resistive (lossy) component of an electromagnetic field and its reactive (lossless) component. It is conveniently defined as the ratio of the imaginary permittivity of a material to its real permittivity, i.e., tan δ=ε″/ε′.

The term “lossy dielectric absorber” as used herein refers to an EMI shielding composite that contains a high-loading-level filler material(s) that can absorb incoming EM radiation at a high frequency regime.

The terms “about” or “approximately” with reference to a numerical value or a shape means +/−five percent of the numerical value or property or characteristic, but expressly includes the exact numerical value. For example, a viscosity of “about” 1 Pa-sec refers to a viscosity from 0.95 to 1.05 Pa-sec, but also expressly includes a viscosity of exactly 1 Pa-sec. Similarly, a perimeter that is “substantially square” is intended to describe a geometric shape having four lateral edges in which each lateral edge has a length which is from 95% to 105% of the length of any other lateral edge, but which also includes a geometric shape in which each lateral edge has exactly the same length.

The term “substantially” with reference to a property or characteristic means that the property or characteristic is exhibited to a greater extent than the opposite of that property or characteristic is exhibited. For example, a substrate that is “substantially” transparent refers to a substrate that transmits more radiation (e.g. visible light) than it fails to transmit (e.g. absorbs and reflects). Thus, a substrate that transmits more than 50% of the visible light incident upon its surface is substantially transparent, but a substrate that transmits 50% or less of the visible light incident upon its surface is not substantially transparent.

As used in this specification and the appended embodiments, the singular forms “a”, “an”, and “the” include plural referents unless the content clearly dictates otherwise. Thus, for example, reference to fine fibers containing “a compound” includes a mixture of two or more compounds. As used in this specification and the appended embodiments, the term “or” is generally employed in its sense including “and/or” unless the content clearly dictates otherwise.

As used in this specification, the recitation of numerical ranges by endpoints includes all numbers subsumed within that range (e.g. 1 to 5 includes 1, 1.5, 2, 2.75, 3, 3.8, 4, and 5).

Unless otherwise indicated, all numbers expressing quantities or ingredients, measurement of properties and so forth used in the specification and embodiments are to be understood as being modified in all instances by the term “about.” Accordingly, unless indicated to the contrary, the numerical parameters set forth in the foregoing specification and attached listing of embodiments can vary depending upon the desired properties sought to be obtained by those skilled in the art utilizing the teachings of the present disclosure. At the very least, and not as an attempt to limit the application of the doctrine of equivalents to the scope of the claimed embodiments, each numerical parameter should at least be construed in light of the number of reported significant digits and by applying ordinary rounding techniques.

The present disclosure describes electromagnetic interference (EMI) shielding composites or articles including about 5 to about 50 wt. % of a low-dielectric-loss matrix material, and about 50 to about 95 wt. % ceramic particles (e.g., CuO particles) distributed inside the low-dielectric-loss matrix material. The low-dielectric-loss matrix material has a dielectric loss tangent in the range of from about 0.0001 to about 0.005, from about 0.0001 to about 0.004, or from about 0.0001 to about 0.003 over the frequency range of interest. The EMI shielding composites or articles described herein are capable of mitigate electromagnetic interference primarily by absorption in the range of, for example, about 0.01 GHz to about 100 GHz, about 1 GHz to about 80 GHz, or about 20 GHz to about 40 GHz.

The composites described herein include a low-dielectric-loss matrix material. Suitable low-dielectric-loss matrix materials can be compoundable with ceramic particles to form the EMI shielding composites. The low-dielectric-loss matrix material described herein has a dielectric loss tangent, for example, less than 0.005, no greater than 0.0045, no greater than 0.004, no greater than 0.0035, no greater than 0.003, no greater than 0.0025, no greater than 0.002 over the frequency range of interest.

In some embodiments, the low-dielectric-loss matrix material may include cured polymeric systems such as, for example, silicone, cyclic olefin copolymer (COC), low-density polyethylene (LDPE), high-density polyethylene (HDPE), polystyrene (PS), polypropylene (PP), polyphenylene sulfide (PPS), polyimide (PI), syndiotactic polystyrene (SPS), polytetrafluoroethylene (PTFE), butyl rubber, acrylonitrile butadiene styrene (ABS), polycarbonate (PC), polyurethane, or a combination thereof. Suitable cured polymeric materials described herein may have a dielectric loss tangent in the range of, for example, from about 0.0001 to about 0.005, from about 0.0001 to about 0.0045, from about 0.0001 to about 0.004, from about 0.0001 to about 0.0035, from about 0.0001 to about 0.003, from about 0.0001 to about 0.0025, or from about 0.0001 to about 0.002 over the frequency range of interest.

In some embodiments, the low-dielectric-loss matrix material may include polymeric materials that are compoundable with copper(II) oxide (CuO) particles. Exemplary compoundable polymeric materials may include silicone, cyclic olefin copolymer (COC), low-density polyethylene (LDPE), high-density polyethylene (HDPE), polystyrene (PS), polypropylene (PP), polyphenylene sulfide (PPS), etc. Suitable compoundable polymeric materials described herein may have a dielectric loss tangent in the range of, for example, from about 0.0001 to about 0.005, from about 0.0001 to about 0.0045, from about 0.0001 to about 0.004, from about 0.0001 to about 0.0035, from about 0.0001 to about 0.003, from about 0.0001 to about 0.0025, or from about 0.0001 to about 0.002 over the frequency range of interest.

In some embodiments, the low-dielectric-loss matrix material may include polymeric foamy systems having closed-cell or open-cell pores. Exemplary foamy systems may include polyurethanes, etc. Suitable foamy materials described herein may have a dielectric loss tangent in the range of, for example, from about 0.0001 to about 0.005, from about 0.0001 to about 0.0045, from about 0.0001 to about 0.004, from about 0.0001 to about 0.0035, from about 0.0001 to about 0.003, from about 0.0001 to about 0.0025, or from about 0.0001 to about 0.002 over the frequency range of interest.

In some embodiments, the low-dielectric-loss matrix material may include ceramic materials including, for example, aluminum oxide (Al₂O₃), silicon oxide (SiO₂), aluminum nitride (AlN), or a combination thereof. Various ceramic fillers including CuO particles can be distributed in the ceramic matrix materials to form EMI shielding articles. Ceramic particles (e.g., CuO particles) distributed inside a polymer matrix are also referred to herein as ceramic fillers. Suitable ceramic materials described herein may have a dielectric loss tangent in the range of, for example, from about 0.0001 to about 0.005, from about 0.0001 to about 0.0045, from about 0.0001 to about 0.004, from about 0.0001 to about 0.0035, from about 0.0001 to about 0.003, from about 0.0001 to about 0.0025, or from about 0.0001 to about 0.002 over the frequency range of interest.

In addition to the low-dielectric-loss matrix material, the EMI shielding composites described herein further include ceramic fillers distributed inside the low-dielectric-loss matrix material to form the composites. In some embodiments, the ceramic fillers can include metal oxide particles such as, for example, copper(II) oxide (CuO) particles. Suitable copper(II) oxide (CuO) particles typically range in size, for example, from an average particle size of 50 nanometers to 50 micrometers, more typically 1 micrometer to 10 micrometers. The copper(II) oxide (CuO) particles can be generally present in an amount of about 40 to about 95 wt. %, about 50 to about 95 wt. %, more typically about 70 to about 95 wt. %. In some embodiments, the copper(II) oxide (CuO) particles can be present in an amount, for example, greater than about 40 wt. %, greater than about 50 wt. %, greater than about 60 wt. %, greater than about 70 wt. %, greater than about 75 wt. %, greater than about 80 wt. %, greater than about 85 wt. %, or greater than about 90 wt. %.

The present disclosure provides polymeric composites including a low-dielectric-loss matrix material for electromagnetic interference (EMI) applications. In one embodiment, the composite includes a high loading level of copper(II) oxide (CuO) fillers distributed in silicone. The present disclosure provides composites including a low-dielectric-loss matrix material having a low dielectric loss tangent, for example, lower than 0.005, lower than 0.0045, lower than 0.004, lower than 0.0035, lower than 0.003, lower than 0.0025, or lower than 0.002. Any polymeric matrix that has the desired intrinsic low dielectric loss properties may be suitable as the polymeric matrix for this disclosure. The low-dielectric-loss matrix material in the present disclosure can help achieve high loadings of filler materials into the composites without using a solvent.

A variety of parameters control the dielectric loss of polymeric matrices. Some of these parameters relate to structural features of the polymers themselves, others relate to the presence of additives. Examples of structural features of the polymers that affect the dielectric loss of the polymeric matrix include the presence of polar groups, the degree of crystallinity, the glass transition temperature (Tg), and the extent of crosslinking Examples of additives that affect the dielectric loss of the polymeric matrix include, for example, plasticizers which can lower the Tg of the polymeric matrix.

A key component contributing to the dielectric loss in polymers is associated with the relaxation of the short polar segments containing groups with high dipole moments. Some examples of such polarized bonds include: C—OR groups where R is a hydrogen atom or an alkyl or aryl group; C—X groups where X is a halogen atom such as a fluorine or chlorine atom; and C—NR1R2 where each R1 and R2 group is independently a hydrogen atom, an alkyl group or an aryl group. The polar segments can either be a part of the backbone structure or on a side chain. In the present disclosure, the low-dielectric-loss matrix material may include less than 5 wt. %, less than 3 wt. %, less than 1 wt. %, less than 0.5 wt. %, less than 0.1 wt. %, or substantially no such polar segments.

The degree of crystallinity is another parameter that affects the dielectric loss in polymers, with more crystalline polymeric matrices having less dielectric loss, because increased crystallinity may reduce the degree of freedom of movement of the polymer chain. In contrast, amorphous polymer matrices have higher free volumes, which may enhance the ease of polymer segment rotation and increases dielectric loss due to absorption of electromagnetic energy. Thus, polymeric matrices with less amorphous regions, and consequently higher crystallinity have lower dielectric loss, i.e. are “less lossy”. The degree of crystallinity in polymers can be controlled by polymer composition and by the choice of processing conditions.

The mobility of the polymer chains is also affected by the glass transition temperature. Even amorphous polymers with high glass transition temperatures (that is to say Tg values that are greater than the use temperature, generally ambient temperature or room temperature) have restricted mobility at the use temperature. Therefore, polymeric matrices that have Tg values that are lower than the use temperature (generally room temperature) are more lossy than polymer matrices with Tg values that are higher than the use temperature. The Tg of the matrix can also be affected by the use of additives. For example, the Tg of the matrix can be lowered by the addition of plasticizers.

The degree of crosslinking in the matrix is especially important in cured polymeric systems such as cured epoxy resin systems. A higher level of crosslinking adversely affects chain segment mobility, and thus lowers the dielectric loss of the matrix. Thus, higher levels of crosslinking are generally desirable for cured polymeric systems to generate low-dielectric-loss matrix materials.

In addition to the above factors, the lossiness of polymeric systems are also affected by factors such as the degree of branching (as branching tends to break up crystallinity), the nature of the resulting end-groups (whether polar or non-polar), the presence of impurities or additives such as unreacted monomers, solvents such as water, processing aids such anti-oxidants, and the like.

WO2014/130431 (Dipankar et al.) discloses the use of CuO fillers in a lossy polymer matrix which has a dielectric loss tangent in the range of 0.005 to 0.5. The lossy polymer matrix material includes a fluorocarbon-based polymer matrix, a chlorine-containing polymer matrix, an epoxy-based polymer matrix, a (meth)acrylate polymer matrix, a polyether polymer matrix, or a combination thereof.

The present disclosure found that it might be difficult to achieve high loadings (e.g., greater than about 80 wt. %, or 40 to 45 vol. %) of filler materials (e.g., dielectric fillers, magnetic fillers, conductive fillers, etc.) in a lossy polymer matrix for thin samples without the use of solvents. Brute forcing a high loading of fillers in such lossy polymer matrix materials may lead to undesired effects such as, for example, agglomerations, cracks in the samples, uneven sample thickness, etc., which may result in undesirable and inconsistent properties of the final EMI shielding articles.

In the present disclosure, the polymeric matrix used to form the composites includes a low-dielectric-loss matrix material such as, for example, silicone. In some embodiments, the low-dielectric-loss matrix material may include non-polar polymer systems. In some embodiments, the polymeric matrix of the EMI shielding composites described herein may include, for example, no less than 80 wt. %, no less than 85 wt. %, no less than 90 wt. %, or no less than 95 wt. % of a low-dielectric-loss matrix material. In some embodiments, the polymeric matrix of the EMI shielding composites described herein may include, for example, no greater than 10 wt. %, no greater than 5 wt. %, no greater than 2 wt. %, no greater than 1 wt. %, no greater than 0.5 wt. %, no greater than 0.2 wt. %, no greater than 0.1 wt. %, or substantially no lossy polymer matrix materials such as the lossy polymer matrix material disclosed in WO2014/130431 (Dipankar et al.).

In some embodiments, the EMI shielding composites including a high-loading-level of ceramic particles (e.g., CuO particles) distributed in a low-dielectric-loss matrix material can exhibit superior dielectric absorber properties, e.g., having a relatively high dielectric loss tangent. In some embodiments, the composites can have a dielectric loss tangent in the range of, for example, about 0.05 to about 0.8, about 0.1 to about 0.8, about 0.2 to about 0.8, or about 0.25 to about 0.75. The high dielectric loss of the composites may attribute to the high-loading-level of ceramic particles (e.g., CuO particles).

In some embodiments, in addition to the low-dielectric-loss matrix material (e.g., silicone) and ceramic particles (e.g., CuO) discussed above, the EMI shielding composites described herein may contain other optional fillers such as, electrically conductive fillers, ferromagnetic fillers, dielectric fillers other than CuO fillers, etc., distributed in the matrix. The optional fillers can be mixed with the ceramic particles and distributed in the matrix material.

A wide range of electrically conductive particles are suitable as optional fillers to form the EMI shielding composites. Suitable electrically conductive particles may include, for example, carbon black, carbon bubbles, carbon foams, graphene, carbon fibers, graphite, graphite nanoplatelets, carbon nanotubes, metal particles and nanoparticles, metal alloy particles, metal nanowires, polyacrylonitrile (PAN) fibers, conductive-coated particles (such as, for example, metal-coated glass particles), or a combination thereof. In some embodiments, carbon black is particularly suitable. Typically, the conductive particles range in size from an average particle size of, for example, about 5 nanometers to about 20 micrometers, more typically from about 5 nanometers to about 500 nanometers. The optional electrically conductive particles can be present in an amount, for example, 0 to 10 wt. %, 0.05 to 10 wt. %, 0.1 to 10 wt. %, more typically 0.5 to 5 wt. % of the final EMI shielding composite.

A wide range of magnetic particles are suitable as optional fillers to form the EMI shielding composites. Suitable magnetic particles may include, for example, a ferromagnetic or ferrimagnetic material including doped or undoped carbonyl iron powder (CIP), iron silicide, ceramic magnetic ferrite, ceramic magnetic garnet, or combinations thereof. In some embodiments, the magnetic fillers may include Fe based alloys such as Sendust (Fe—Si—Al), Fe-silicide (Fe—Si—Cr), Carbonyl Iron, or an alloy of iron and nickel, a ceramic ferrite, or a combination thereof. The optional magnetic particles can be present in an amount, for example, 0 to 40 wt. %, 2 to 40 wt. %, 5 to 40 wt. %, more typically 20 to 40 wt. % of the final EMI shielding composite.

In some embodiments, the EMI shielding composites may further include, for example, about 5 to about 40 wt. %, or about 10 to about 30 wt. % of optional dielectric fillers other than CuO fillers. The dielectric filler may include doped or undoped TiO, SiC, or mixtures thereof.

In some embodiments, the EMI shielding composites may further include, for example, about 5 to about 40 wt. %, or about 10 to about 30 wt. % of optional multiferroic fillers such as, for example, BiFeO₃, BiMnO₃, or mixtures thereof.

The present disclosure provides various methods of making the EMI shielding composites. In some embodiments, the methods may include providing ceramic particles such as, for example, CuO particles. The ceramic particles can be compounded with a low-dielectric-loss matrix material such as, for example, silicone. In some embodiments, CuO particles can be mixed with two parts of silicone elastomer. The loading level of ceramic particles (e.g., CuO particles) can be as high as, for example, about 40 to about 95 wt. %, about 50 to about 95 wt. %, about 60 to about 95 wt. %, about 70 to about 95 wt. %, about 80 to about 95 wt. %, about 85 to about 95 wt. %, or about 90 to about 95 wt. %. In some embodiments, the loading level of CuO particles in the composites can be, for example, greater than about 40 wt. %, greater than about 50 wt. %, greater than about 60 wt. %, greater than about 70 wt. %, greater than about 80 wt. %, or greater than about 90 wt. %. In some embodiments, the majority (i.e., greater than about 50 wt. %) of the composite can be CuO particles. Optional dispersants, such as silica, silane agents, etc., can be added during the mixing. Also, optional fillers (e.g., electrically conductive fillers, magnetic fillers, dielectric fillers, etc.) can be added into the mixture to achieve desired properties.

The mixture of the low-dielectric-loss matrix and various fillers distributed therein can be further processed to form EMI shielding composites. In some embodiments, the matrix material may include a curable matrix material, and the mixture can be cured by heat or radiation to form composites. In some embodiments, the mixture can be thermal-processed under a pressure to form a desired shape (e.g., a sheet). Other suitable processes such as, for example, molding, extrusion, micro-replication, etc., can also be used to further process the mixture to form final EMI shielding articles having desired shapes and compositions.

In the present disclosure, the ceramic particles (e.g., CuO particles) are introduced to mix with a polymeric low-dielectric-loss matrix material (e.g., silicone), and optionally with other desired fillers to form polymeric composites. In some embodiments, the ceramic particles can be uniformly dispersed in the polymeric matrix material to form a homogenous composite. In some embodiments, the ceramic particles can be unevenly dispersed in the matrix material. For example, a graded layer approach may be taken where the ceramic particles and/or other magnetic/dielectric fillers have a graded distribution so that the EMI shielding composite is compositionally graded to reduce impedance mismatch between the EMI shielding composite and free space. In some embodiments, other types of fillers including, for example, electrically conductive fillers, dielectric fillers, mixtures thereof, etc., can be mixed with the ceramic particles, and dispersed into the polymeric matrix material to achieve desired thermal, mechanical, electrical, magnetic, and/or dielectric properties.

The EMI shielding composites described herein can exhibit superior dielectric absorber performance and mechanical properties. The dielectric absorber performance can be improved by increasing loading level of ceramic particles (e.g., CuO particles). When the loading level of ceramic particles or fillers in a lossy dielectric matrix material is above a certain range, stiffness of the composite can be too high such that an EMI shielding article made from the composite may exhibit poor mechanical properties (e.g., brittle or easy to crumble). In the present disclosure, the loading level of ceramic particles (e.g., CuO) in a low-dielectric-loss matrix material (e.g., silicone) can be increased to a range (e.g., 90 wt. % or higher) to obtain superior dielectric absorber performance, while keeping the corresponding stiffness sufficiently low. This opens a window for obtaining high-loading-level CuO particles for the application of high frequency EMI absorption.

The EMI shielding composites described herein can be used for various EMI applications. In some embodiments, a printable ink can be made from the EMI shielding composites. Inks can be made from the composites described herein by any suitable processes. The ink can be suitable for printing on a substrate to mitigate electromagnetic interference (EMI) in an IC circuit. In some embodiments, the ink may include a matrix solution and ceramic particles dispersed within the matrix solution, where the ceramic particles are or include copper oxide (CuO). In some embodiments, the matrix solution may be or include a polymer dissolved in a solvent, and the polymer may also include a copolymer. In some embodiments, the ink may be configured to produce, after the solvent is removed, a solid and/or cured composite material having the polymer as a matrix material and the ceramic particles dispersed in the matrix material.

In some embodiments, an EMI ink can be formulated in a liquid or viscous medium and can be readily applied to a substrate to impart the desired EM shielding properties to the printed surface. The EMI filler (e.g., CuO particles) can be mixed with a polymer binder using known formulation technology. The particles can form a suspension or colloidal mixture in the polymer in a flowable state. When the coating or ink is applied to the substrate and cured to form a solid coating, the particles can form a continuous path on the substrate thereby providing the desirable EMI shielding effects. The EMI inks can be applied onto various surfaces using methods such as or screen or pad printing, spray painting, dipping and syringe dispensing. Products can be applied to flexible or rigid substrates and can be printed on uneven or complex contoured surfaces with good adhesion.

Exemplary embodiments of the present disclosure may take on various modifications and alterations without departing from the spirit and scope of the present disclosure. Accordingly, it is to be understood that the embodiments of the present disclosure are not to be limited to the following described exemplary embodiments, but is to be controlled by the limitations set forth in the claims and any equivalents thereof.

Various exemplary embodiments of the disclosure will now be described with particular reference to the Drawings. Exemplary embodiments of the present disclosure may take on various modifications and alterations without departing from the spirit and scope of the disclosure. Accordingly, it is to be understood that the embodiments of the present disclosure are not to be limited to the following described exemplary embodiments, but are to be controlled by the limitations set forth in the claims and any equivalents thereof.

### Listing of Exemplary Embodiments

Exemplary embodiments are listed below. It is to be understood that any one of embodiments 1-19, 20-22 and 23-26 can be combined.

Embodiment 1 is an electromagnetic interference (EMI) shielding composite comprising:

about 5 to about 50 wt. % of a low-dielectric-loss matrix material; and

about 50 to about 95 wt. % ceramic particles distributed inside the low-dielectric-loss matrix material,

wherein the low-dielectric-loss matrix material has a dielectric loss tangent in the range of about 0.0001 to about 0.005.

Embodiment 2 is the composite of embodiment 1, wherein the ceramic particles include metal oxide particles, the composite comprises at least 70 wt. % of the metal oxide particles.

Embodiment 3 is the composite of embodiment 2, wherein the metal oxide particles comprise CuO.

Embodiment 4 is the composite of any one of embodiments 1-3, wherein the low-dielectric-loss matrix material comprises one or more low-dielectric-loss polymer materials.

Embodiment 5 is the composite of embodiment 4, wherein the one or more low-dielectric-loss polymer materials include silicone.

Embodiment 6 is the composite of embodiment 4, wherein the one or more low-dielectric-loss polymer materials include one or more of cyclic olefin copolymer (COC), low-density polyethylene (LDPE), high-density polyethylene (HDPE), polystyrene (PS), polypropylene (PP), polyphenylene sulfide (PPS), polyimide (PI), syndiotactic polystyrene (SPS), polytetrafluoroethylene (PTFE), butyl rubber, acrylonitrile butadiene styrene (ABS), polycarbonate (PC), polyurethane, or a combination thereof.

Embodiment 7 is the composite of embodiment 4, wherein the one or more low-dielectric-loss polymer materials include a foamy material having closed-cell or open-cell pores.

Embodiment 8 is the composite of any one of embodiments 1-7, wherein the low-dielectric-loss matrix material comprises one or more low-dielectric-loss ceramic materials.

Embodiment 9 is the composite of embodiment 8, wherein the one or more low-dielectric-loss ceramic materials include aluminum oxide (Al₂O₃), silicon oxide (SiO₂), aluminum nitride (AlN), or a combination thereof.

Embodiment 10 is the composite of any one of embodiments 1-9 comprising about 0 to about 10 wt. % electrically conductive fillers.

Embodiment 11 is the composite of embodiment 10 comprising about 0.1 to about 10 wt. % electrically conductive fillers.

Embodiment 12 is the composite of any one of embodiments 1-11, which has a dielectric loss tangent in the range of about 0.05 to about 0.8.

Embodiment 13 is the composite of any one of embodiments 1-12, which has a dielectric loss tangent in the range of about 0.25 to about 0.75.

Embodiment 14 is the composite of any one of embodiments 1-13 further comprising about 0.05 to about 10 wt. % dispersant.

Embodiment 15 is the composite of any one of embodiments 1-14 further comprising about 5 to about 40 wt. % of one or more magnetic fillers.

Embodiment 16 is the composite of embodiment 15, wherein the magnetic fillers include an Fe based alloys including one or more of Sendust (Fe—Si—Al), Fe-silicide (Fe— Si—Cr), carbonyl iron, or an alloy of iron and nickel, a ceramic ferrite, or a combination thereof.

Embodiment 17 is an electromagnetic interference (EMI) shielding article comprising the composite of any one of the preceding embodiments.

Embodiment 18 is the EMI shielding article of embodiment 17, which is capable of shielding, primarily by absorbing, electromagnetic radiation in the range of about 0.01 GHz to about 100 GHz.

Embodiment 19 is the EMI shielding article of embodiment 18, which is capable of shielding, primarily by absorbing, electromagnetic radiation in the range of about 20 GHz to about 40 GHz.

Embodiment 20 is a method of making the composite of any one of embodiments 1-19, the method comprising compounding the ceramic particles with the low-dielectric-loss polymer matrix to form the composite.

Embodiment 21 is the method of embodiment 20 further comprising shaping the composite into a composite sheet that is substantially free of visible cracks.

Embodiment 22 is the method of embodiment 20 or 21 further comprising forming a printable ink comprising the composite.

Embodiment 23 is an electromagnetic interference (EMI) shielding composite comprising:

about 5 to about 50 wt. % of a low-dielectric-loss matrix material;

about 50 to about 95 wt. % copper(II) oxide (CuO) particles distributed inside the low-dielectric-loss matrix material; and

about 0.1 to about 10 wt. % carbon black fillers distributed inside the low-dielectric-loss matrix material,

wherein the low-dielectric-loss matrix material has a dielectric loss tangent in the range of about 0.0001 to about 0.005.

Embodiment 24 is the composite of embodiment 23 comprising about 0.3 to about 4 wt. % carbon black fillers.

Embodiment 25 is the composite of embodiment 23 comprising about 0.3 to about 2 wt. % carbon black fillers.

Embodiment 26 is the composite of any one of embodiments 23-25, wherein the one or more low-dielectric-loss polymer materials include silicone.

Embodiment 27 is the composite of embodiment 23 further comprising carbon nanotubes distributed inside the low-dielectric loss matrix material.

Embodiment 28 is the composite of any one of embodiments 10-11, wherein the electrically conductive fillers are selected from the group consisting of carbon black, carbon bubbles, carbon foams, graphene, carbon fibers, graphite, graphite nanoplatelets, carbon nanotubes, metal particles and nanoparticles, metal alloy particles, metal nanowires, polyacrylonitrile (PAN) fibers, conductive-coated particles, and combinations thereof.

Embodiment 29 is the composite of embodiment 28, wherein the conductive-coated particles comprise metal-coated glass particles.

Embodiment 30 is the composite of embodiment 1 comprising about 0.1 to about 10 wt. % electrically conductive fillers distributed inside the low-dielectric loss matrix material, the electrically conductive fillers selected from the group consisting of carbon black, carbon nanotubes, and a combination thereof.

The operation of the present disclosure will be further described with regard to the following detailed examples. These examples are offered to further illustrate the various specific and preferred embodiments and techniques. It should be understood, however, that many variations and modifications may be made while remaining within the scope of the present disclosure.

### EXAMPLES

These Examples are merely for illustrative purposes and are not meant to be overly limiting on the scope of the appended claims. Notwithstanding that the numerical ranges and parameters setting forth the broad scope of the present disclosure are approximations, the numerical values set forth in the specific examples are reported as precisely as possible. Any numerical value, however, inherently contains certain errors necessarily resulting from the standard deviation found in their respective testing measurements. At the very least, and not as an attempt to limit the application of the doctrine of equivalents to the scope of the claims, each numerical parameter should at least be construed in light of the number of reported significant digits and by applying ordinary rounding techniques.

### Summary of Materials

Table 1 below provides abbreviations and a source for all materials used in the Examples 1-4 below:

TABLE 1

| Abbreviation | Description | Source |
|---|---|---|
| CuO Filler-1 | Copper Oxide (99%) | Alfa Aesar, Ward Hill, |
| | | MA. |
| CuO Filler-2 | Copper Oxide (98%) | Sigma Aldrich, St. Louis, |
| | | MO. |
| Colloidal | Colloidal silica | Nalco, Bedford Park, IL. |
| silica | | |
| ITMS | Isoctyltrimethoxy silane | Gelest, Morrisville, PA. |
| MTMS | Methyltrimethoxy silane | Gelest, Morrisville, PA. |
| 80:20 EtOH | 80:20 wt./wt. % solvent blend of | EMD, Gibbstown, NJ. |
| | ethanol:methanol | |
| MeOH | Methanol | VWR, West Chester, PA. |
| Sylgard 184 | Two-part silicone elastomer kit | Dow Corning, Midland, |
| | | MI. |

### Test Methods

For all the examples described herein, complex dielectric and magnetic properties were calculated from S parameters obtained using an Agilent E8363C Network Analyzer (from Agilent Technologies, Santa Clara, Calif.) over the frequency range of 18 to 26.5 GHz (K Band) using rectangular waveguides made using the silicone composites described below. Silicone samples (smooth and uniform) were cut to fit into the transmission lines and sized to have as small an air-gap as possible inside the transmission line.

### Preparative Example 1: Hydrophobic Nanosilica

To prepare hydrophobically modified nanosilica particles, 100 grams of colloidal silica (16.06 wt. % solids in water; 5 nm size), 7.54 grams of isoctyltrimethoxy silane (ITMS), 0.81 grams of methyltrimethoxysilane (MTMS), and 112.5 grams of an 80:20 ethanol (80:20 wt./wt. % solvent blend of ethanol:methanol) were added to a 500 mL 3-neck round bottom flask (Ace Glass, Vineland, N.J., USA). The flask containing the mixture was placed in an 80° C. oil bath for 4 hours while stirring. The prepared hydrophobically modified nanosilica particles were then transferred to a crystallizing dish and dried in a convection oven at 150° C. for 2 hours. The hydrophobic nanosilica will be used for all the examples described herein.

### Example 1: Silicone Composites with CuO (99% Chemical Purity) as Fillers and Nanosilica as Dispersants

In a plastic cup, the required amount of Sylgard 184 Part A was degassed under vacuum for 10-15 minutes. The required amount of Sylgard 184 Part B, the curing agent, was then added to the degassed Part A. To this mixture was added 90 wt. % CuO Filler-1 (99% chemical purity), and 1 wt. % nanosilica. The nano silica was added as a dispersant. The plastic cup was covered with a cap configured to allow speed mixing under vacuum (100 mbar) for 2 minutes and 15 seconds. The mixture was then poured onto a stainless steel plate. A second stainless steel plate was placed on top of the mixture and appropriate spacers were used between the two plates to separate them to a desired thickness. The plates containing the mixture were hot pressed at a temperature of 118° C. under a pressure of 3 tons for 45-60 minutes. The plates were allowed to cool for 30-45 minutes before the cured composite sheet was removed.

### Example 2: Silicone Composites with CuO (98% Chemical Purity) as Fillers and Nanosilica as Dispersants

Similar process as in Example 1 was used to make a 90 wt. % CuO silicone composite using CuO Filler-2 (98% chemical purity) powders.

### Example 3: Silicone Composites with CuO (99% Chemical Purity) as Fillers

Silicone composites were made using the amounts of CuO Filler-1 as in Example 1 but without the addition of nanosilica as dispersants.

### Example 4: Silicone Composites with CuO (98% Chemical Purity) as Fillers

Silicone composites were made using the amounts of CuO Filler-2 as in Example 2 but without the addition of nanosilica as dispersants.

### Results

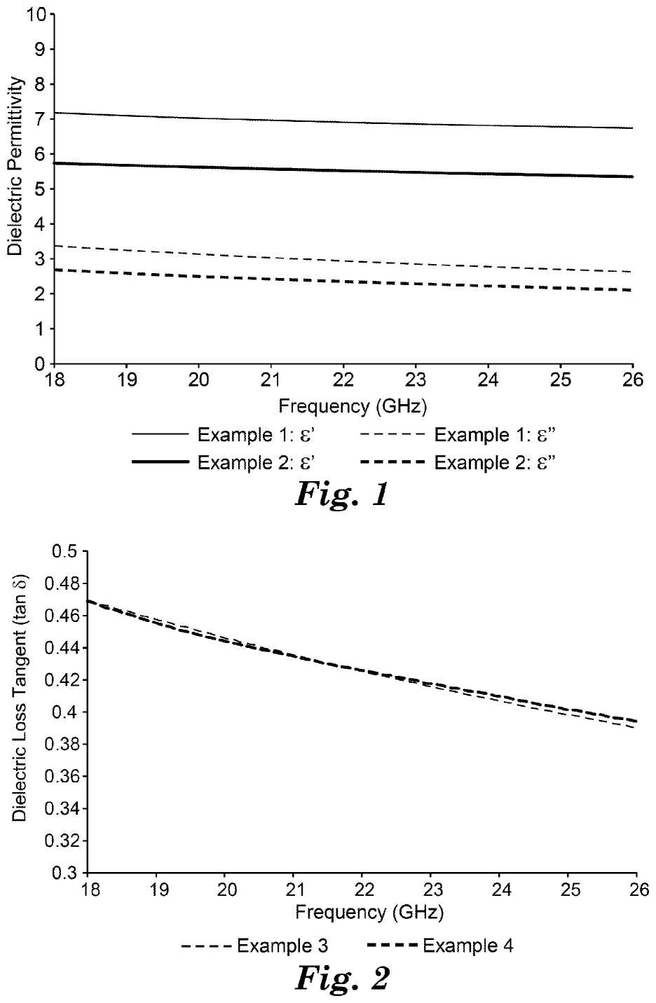

Polymeric composites of Examples 1-4 were evaluated with respect to their dielectric permittivity properties and the results are shown in FIGS. 1-3, respectively.

As shown in FIG. 1, Examples 1 and 2 exhibit high dielectric loss values (ε″) which can translate to high absorber performance. In addition, the ε′ values of Examples 1 and 2 are low to moderate which means that reflection values can be minimized. Much lower frequency dispersion is observed here compared to composites with conductive fillers, which could be an advantage while designing EMI absorbers for a flat band response. Different from typical ceramics which display low dielectric loss properties, Examples 1 and 2 exhibit unique dielectric properties (high dielectric loss) that make the compositions suitable for EMI applications.

FIG. 2 shows the dielectric loss tangent (tan δ=ε″/ε′) vs. frequency for Examples 3 and 4, respectively. It shows that the tan δ values for the two different examples are very similar even though from FIG. 1, the dielectric polarization for the higher purity examples (Example 1) seem to be higher. Once again very high loss is observed over this frequency range which makes the composites of Examples 3 and 4 very useful as a dielectric absorber for high frequency EMI applications.

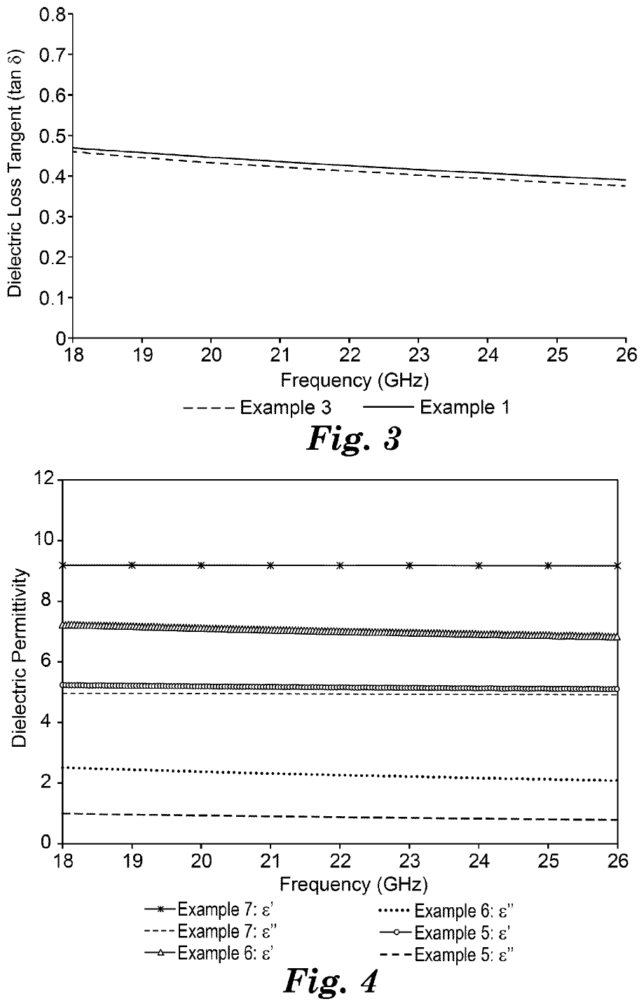

FIG. 3 exhibits that even without adding any dispersants in the composite of Example 3, it is possible to get very high dielectric loss tangent values for the composites. The dielectric loss tangent values for the two different samples (Examples 1 and 3) are very similar. Also, the frequency dispersion characteristics of the composites are subdued which might be beneficial for EMI engineers who sometimes prefer flat band characteristics for EMI/EMC composites across the frequency band of interest.

### Summary of Materials

Table 2 below provides abbreviations and a source for all materials used in the Examples 5-7 below:

TABLE 2

| Abbreviation | Description | Source |
|---|---|---|
| CuO Filler-3 | Copper Oxide (>98%) | American Chemet, |
| | | Deerfield, IL |
| Carbon black, CB | Electro-conductive carbon black obtained | Azko Nobel Polymer |
| | under the trade designation KETJENBLACK | Chemicals LLC, |
| | EC600JD | Chicago, IL |
| SA-PDMS | Succinic anhydride terminated | Gelest Inc., Morrisville, |
| | polydimethylsiloxane obtained under the | PA |
| | product code #DMS-Z21 | |
| SYLGARD 184 | Two-part silicone elastomer kit obtained | Dow Corning, Midland, |
| | under the trade designation SYLGARD 184 | MI |
| | (the two parts include Part A - SLYGARD | |
| | 184 SILICOME ELASTOMER BASE and | |
| | Part B - SYLGARD 184 SILICONE | |
| | ELASTOMER CURING AGENT) | |

### Example 5: Silicone Composites with CuO (80 wt. %) as Fillers

In a plastic cup, the required amount of SYLGARD 184 Part A (SYLGARD 184 SILICONE ELASTOMER BASE, Dow Corning, Midland, Mich.) was degassed under vacuum for 10-15 minutes. The required amount of SYLGARD 184 Part B, the curing agent (SYLGARD 184 SILICONE ELASTOMER CURING AGENT, Dow Corning), was then added to the degassed Part A. To this mixture was added 80 wt. % CuO Filler-3 (from American Chemet, Deerfield, Ill.) and 1.75 wt. % succinic anhydride terminated polydimethylsiloxane (SA-PDMS) (obtained under the product code # DMS-Z21 from Gelest, Inc., Morrisville, Pa.). The SA-PDMS was added as a dispersant. The plastic cup was covered with a cap configured to allow speed mixing under vacuum (100 mbar) for 2 minutes and 15 seconds. The mixture was then poured onto a stainless steel plate. A second stainless steel plate was placed on top of the mixture and appropriate spacers were used between the two plates to separate them to a desired thickness. The plates containing the mixture were hot pressed at a temperature of 118° C. under a pressure of 3 tons for 45-60 minutes. The plates were allowed to cool for 30-45 minutes before the cured composite sheet was removed.

### Example 6: Silicone Composites with CuO (80 wt. %) and Carbon Black (0.6 wt. %) as Fillers

Silicone composites were made using the same amount of CuO Filler-3 (80 wt. %) as in Example 5, with the addition of 0.6 wt % carbon black filler (KETJENBLACK EC600JD carbon black, Azko Nobel Polymer Chemicals LLC, Chicago, Ill.).

### Example 7: Silicone Composites with CuO (80 wt. %) and Carbon Black (1 wt. %) as Fillers

Silicone composites were made using the same amount of CuO Filler-3 (80 wt. %) as in Example 5, with the addition of 1 wt % carbon black filler (KETJENBLACK EC600JD carbon black, Azko Nobel Polymer Chemicals LLC).

FIG. 4 illustrates plots for real and imaginary part of dielectric permittivity (Eps (Re)=ε′ and Eps (Im)=ε″) vs. frequency for (a) Example 5 containing CuO (80 wt. % loading) (b) Example 6 containing CuO (80 wt. %) plus carbon black (CB, 0.6 wt. %) and (c) Example 7 containing CuO (80 wt. %) plus CB (1 wt. %) in silicone matrix polymer composites. ε′ is shown with the solid lines. ε″ is shown with the dashes lines.

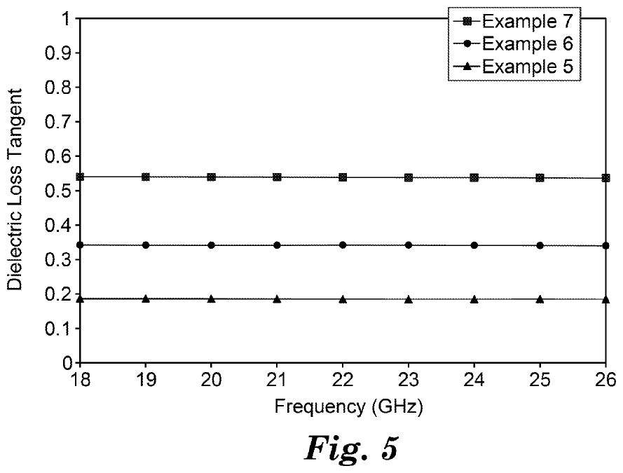

FIG. 5 illustrates plots for dielectric loss tangent (tan δ=ε″/ε′) vs. frequency for (a) Example 5 containing CuO (80 wt. % loading) (b) Example 6 containing CuO (80 wt. %) plus CB (0.6 wt. %) and (c) Example 7 containing CuO (80 wt. %) plus CB (1 wt. %) in silicone matrix polymer composites. As shown in FIGS. 4 and 5, the dielectric loss increases as the CB concentration is increased. This enhanced dielectric loss is important for EMI applications.

Reference throughout this specification to “one embodiment,” “certain embodiments,” “one or more embodiments” or “an embodiment,” whether or not including the term “exemplary” preceding the term “embodiment,” means that a particular feature, structure, material, or characteristic described in connection with the embodiment is included in at least one embodiment of the certain exemplary embodiments of the present disclosure. Thus, the appearances of the phrases such as “in one or more embodiments,” “in certain embodiments,” “in one embodiment” or “in an embodiment” in various places throughout this specification are not necessarily referring to the same embodiment of the certain exemplary embodiments of the present disclosure. Furthermore, the particular features, structures, materials, or characteristics may be combined in any suitable manner in one or more embodiments.

While the specification has described in detail certain exemplary embodiments, it will be appreciated that those skilled in the art, upon attaining an understanding of the foregoing, may readily conceive of alterations to, variations of, and equivalents to these embodiments. Accordingly, it should be understood that this disclosure is not to be unduly limited to the illustrative embodiments set forth hereinabove. In particular, as used herein, the recitation of numerical ranges by endpoints is intended to include all numbers subsumed within that range (e.g., 1 to 5 includes 1, 1.5, 2, 2.75, 3, 3.80, 4, and 5). In addition, all numbers used herein are assumed to be modified by the term “about.” Furthermore, various exemplary embodiments have been described. These and other embodiments are within the scope of the following claims.

1. An electromagnetic interference (EMI) shielding composite comprising:
about 5 to about 50 wt. % of a low-dielectric-loss matrix material; and
about 50 to about 95 wt. % copper(II) oxide (CuO) particles distributed inside the low-dielectric-loss matrix material,
wherein the low-dielectric-loss matrix material has a dielectric loss tangent in the range of about 0.0001 to about 0.005.

2. The composite of claim 1 comprising at least 70 wt. % of the CuO particles.

3. The composite of claim 1, wherein the low-dielectric-loss matrix material comprises one or more low-dielectric-loss polymer materials.

4. The composite of claim 3, wherein the one or more low-dielectric-loss polymer materials include silicone.

5. The composite of claim 3, wherein the one or more low-dielectric-loss polymer materials include one or more of cyclic olefin copolymer (COC), low-density polyethylene (LDPE), high-density polyethylene (HDPE), polystyrene (PS), polypropylene (PP), polyphenylene sulfide (PPS), polyimide (PI), syndiotactic polystyrene (SPS), polytetrafluoroethylene (PTFE), butyl rubber, acrylonitrile butadiene styrene (ABS), polycarbonate (PC), polyurethane, or a combination thereof.

6. The composite of claim 3, wherein the one or more low-dielectric-loss polymer materials include a foamy material having closed-cell or open-cell pores.

7. The composite of claim 1, wherein the low-dielectric-loss matrix material comprises one or more low-dielectric-loss ceramic materials.

8. The composite of claim 7, wherein the one or more low-dielectric-loss ceramic materials include aluminum oxide (Al₂O₃), silicon oxide (SiO₂), aluminum nitride (AlN), or a combination thereof.

9. The composite of claim 1 comprising about 0.1 to about 10 wt. % electrically conductive fillers.

10. The composite of claim 9, wherein the electrically conductive fillers are selected from the group consisting of carbon black, carbon bubbles, carbon foams, graphene, carbon fibers, graphite, graphite nanoplatelets, carbon nanotubes, metal particles and nanoparticles, metal alloy particles, metal nanowires, polyacrylonitrile (PAN) fibers, conductive-coated particles, and combinations thereof.

11. The composite of claim 1, comprising about 0.1 to about 10 wt. % electrically conductive fillers distributed inside the low-dielectric loss matrix material, the electrically conductive fillers selected from the group consisting of carbon black, carbon nanotubes, and a combination thereof.

12. The composite of claim 1 further comprising about 2 to about 40 wt. % of one or more magnetic fillers.

13. The composite of claim 1, which has a dielectric loss tangent in the range of about 0.05 to about 0.8.

14. The composite of claim 1, which has a dielectric loss tangent in the range of about 0.25 to about 0.75.

15. An electromagnetic interference (EMI) shielding article comprising the composite of claim 1.

16. A method of making the composite of claim 1, the method comprising compounding the CuO particles with the low-dielectric-loss polymer matrix to form the composite.

17. An electromagnetic interference (EMI) shielding composite comprising:
about 5 to about 50 wt. % of a low-dielectric-loss matrix material;
about 50 to about 95 wt. % copper(II) oxide (CuO) particles distributed inside the low-dielectric-loss matrix material; and
about 0.1 to about 10 wt. % carbon black fillers distributed inside the low-dielectric-loss matrix material,
wherein the low-dielectric-loss matrix material has a dielectric loss tangent in the range of about 0.0001 to about 0.005.

18. The composite of claim 17 comprising about 0.3 to about 4 wt. % carbon black fillers.

19. The composite of claim 17 comprising about 0.3 to about 2 wt. % carbon black fillers.

20. The composite of claim 17, wherein the one or more low-dielectric-loss polymer materials include silicone.
